(19) United States
(12) Patent Application Publication
(10) Pub. No.: US 2007/0080394 A1
(43) Pub. Date: Apr. 12, 2007

(54) Nonvolatile memory

(76) Inventor: Akihiko Ohara, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/541,671

(22) Filed: Oct. 3, 2006

(30) Foreign Application Priority Data
Oct. 12, 2005 (JP) 2005-297159

(51) Int. Cl. H01L 29/788

(52) U.S. Cl. 257/316

(57) ABSTRACT

A nonvolatile memory includes a plurality of drain regions and a plurality of source regions, and a plurality of control gate regions. The drain regions and the source regions are formed on a semiconductor chip so as to extend parallel to each other and extend between opposite ends of the semiconductor chip, and resistances of the source regions per unit length along its longitudinal direction are higher than resistances of the drain regions per unit length along its longitudinal direction. The control gate regions are formed on the semiconductor chip to extend in a direction perpendicular to the drain regions and the source regions. With this arrangement, the cell size can be reduced without causing deterioration of the writing characteristic and increase of the off leak current.

### BACKGROUND OF THE INVENTION

1. Field of the Invention

The present invention relates to a nonvolatile memory having a bit line assembly consisting of bit lines formed by diffused layers.

2. Description of the Related Art

A nonvolatile memory having a bit line assembly consists of a plurality of bit lines which are formed by impurity diffused layers. Namely, the impurity diffused layers serve as source regions and drain regions. The nonvolatile memory generally includes a plurality of bit lines and a plurality of control gates which are arranged perpendicular to each other to form a memory cell array (see Japanese Patent Kokai No. H6-196711, for example).

Referring to FIGS. 1A and 1B, a conventional nonvolatile memory will be hereinafter described which has abit line assembly consisting of bit lines formed by diffused layers as shown in Japanese Patent Kokai No. H6-196711. FIGS. 1A and 1B schematically illustrate the conventional nonvolatile memory which has the bit line assembly. Specifically, FIG. 1A is a schematic front view of the conventional nonvolatile memory, and FIG. 1B is a schematic partial enlarged sectional view of FIG. 1A along the line A-A.

As can be understood from these figures, on a semiconductor chip 210, a plurality of impurity diffused layers 220 are provided to form a striped shape so as to respectively serve as bit lines. A plurality of control gate regions 230 are provided to form a striped shape extending in a direction perpendicular to a longitudinal direction of the impurity diffused layers 220.

The impurity diffused layers 220 are arranged side by side along a longitudinal direction of the control gate regions 230 so as to alternately serve as drain regions 222 and source regions 224. In the nonvolatile memory, a memory cell is defined at an intersection of the neighboring drain region 222 and source region 224 and one of the control gate regions 230 as shown by a dotted line I in FIG. 1A.

Each memory cell of the nonvolatile memory is provided with a floating gate 240. The floating gate 240 is formed on the semiconductor chip 210 via a floating gate insulation film 245, and the floating gate 240 is arranged between the drain region 222 and the source region 224. The control gate region 230 is formed either on the floating gate 240 via the control gate insulation film 235 or on the semiconductor chip 210 via an interlayer insulation film 250.

In the case of the conventional nonvolatile memory shown in FIGS. 1A and 1B, an area of each memory cell is defined by the following factors, i.e., a width of the drain region 222 and a width of the source region 224, a gap between the drain region 222 and the source region 224, and a width of the control gate region 230 and a gap between the control gate regions 230. For example, a width W_{D} of the drain region 222 is 0.14 μm and a width W_{S} of the source region 224 is 0.14 μm, a gap between the drain region 222 and the source region 224, i.e., a clearance D_{DS} between facing edges of the drain region 222 and the source region 224, is 0.14 μm, and a width of the control gate region 230 W_{G} is 0.14 μm and a gap D_{G} between adjacent control gate regions 230 is 0.14 μm. A source resistance and a drain resistance, which are respectively determined by the width or a cross sectional area of the source region 224 and the width or a cross sectional area of the drain region 222, and further determined by impurity concentration of the impurity diffused layer, are respectively about 10 kΩ. It should be noted that the source resistance is defined by an electric resistance of the source region 224 measured between opposite ends of the source region 224 along its longitudinal direction. Similarly, the drain resistance is defined by an electric resistance of the drain region 222 measured between opposite ends of the drain region 222 along its longitudinal direction.

In order to decrease the area of the memory cell, it may be necessary to decrease the widths of the impurity diffused layers serving as the source region and the drain region. However decrease in width of the impurity diffused layers increases the resistance of the bit lines, thereby affecting a writing characteristic of the nonvolatile memory. It should be noted that the writing of the nonvolatile memory represents injection of hot electrons into the floating gate, and the writing characteristic of the nonvolatile memory is evaluated by a difference ΔVt between a threshold voltage Vt before the writing and that after the writing.

FIG. 2 is a graph showing a relationship between the writing characteristic of the nonvolatile memory and a summation of the source resistance and the drain resistance. In FIG. 2, an abscissa axis represents the summation of the source resistance and the drain resistance in kΩ, and an ordinate axis represents the writing characteristic of the nonvolatile memory, i.e., the difference ΔVt(V) between the threshold voltage before the writing and the threshold voltage after the writing. In the conventional nonvolatile memory, the source region and the drain region are generally made to have the same characteristics, such as electrical resistances, so as to be able to replace the source region with the drain region.

As the summation of the source resistance and the drain resistance increases up to 40 kΩ, the difference ΔVt of the threshold voltages remains substantially constant within a range between approximately 3.7 V and 3.9 V. When the summation of the source resistance and the drain resistance reaches 60 kΩ, the difference ΔVt of the threshold voltages suddenly falls to approximately 1.8 V. That is to say, when the summation of the source resistance and the drain resistance reaches 60 kΩ, the writing characteristic of the nonvolatile memory deteriorates.

In order to reduce the source resistance and the drain resistance under the condition in that the impurity diffused layers have narrow widths, it may be effective to increase the impurity concentration of the impurity diffused layer. However, increase of the impurity concentration decreases a sheet resistance. When the sheet resistance becomes 500 (Ω/□) or below, an off leak current may increase. Accordingly, reduction of the source resistance and the drain resistance by the increase of the impurity concentration has a certain limitation.

An inventor of the subject application has thus been dedicated to study and has discovered the fact that increase of the drain resistance deteriorates the writing characteristic, whereas increase of the source resistance does not deteriorate the writing characteristic.

FIG. 3 is a graph showing a relationship between the writing characteristic of the nonvolatile memory and the drain resistance. In this graph, the summation of the source resistance and the drain resistance is constant at 40 kΩ. In FIG. 3, a bottom abscissa axis shows a drain resistance in kΩ, and a top abscissa axis shows a source resistance in kΩ. Since the summation of the drain resistance and the source resistance remains constant, increase of the drain resistance represents decrease of the source resistance, whereas decrease of the drain resistance represents increase of the source resistance. An ordinate axis shows the writing characteristic of the nonvolatile memory, i.e., the difference ΔVt(V) between the threshold voltage before the writing and that after the writing. In this graph, voltages applied to the gate region, source region and drain region during the writing are 8V, 0V and 4.5V, respectively.

As shown in FIG. 3, as the drain resistance increases up to 20 kΩ, the difference ΔVt between the threshold voltages is substantially constant within a range between 3.7 and 3.9 V. When the drain resistance further increases to reach 30 kΩ, even though the summation of the source resistance and the drain resistance remains at 40 kΩ, the difference ΔVt between the threshold voltages falls to approximately 1.5 V. That is to say, when the drain resistance exceeds 20 kΩ and reaches 30 kΩ, the writing characteristic deteriorates. On the other hand, when the drain resistance decreases and becomes 10 kΩ or below, even though the source resistance exceeds 30 kΩ, the writing characteristic does not deteriorate.

### SUMMARY OF THE INVENTION

The present invention is provided in an attempt to overcome the above described problem in that the writing characteristic of the nonvolatile memory having a bit line assembly consisting of bit lines formed by diffused layers deteriorates when the summation of the source resistance and the drain resistance is increased. Accordingly, an object of the present invention is to provide a nonvolatile memory having memory cells with reduced areas without causing deterioration of the writing characteristic of the memory cell and increase of the off leak current.

In order to attain the above object, a nonvolatile memory having a bit line assembly consisting of bit lines formed by diffused layers according to the present invention has a plurality of drain regions and a plurality of source regions, and a plurality of control gate regions.

The drain regions and the source regions are formed on a semiconductor chip so as to extend parallel to each other and extend between opposite ends of the semiconductor chip, and resistances of the source regions per unit length along its longitudinal direction are higher than resistances of the drain regions per unit length along its longitudinal direction. The control gate regions are formed on the semiconductor chip to extend in a direction perpendicular to the drain regions and the source regions.

According to a nonvolatile memory having a bit line assembly consisting of bit lines formed by diffused layers of the present invention, a distance along a direction parallel to an extending direction of the control gate region and extending between a center of a drain width and a center of a source width is shorter than a distance between a center of a drain width and a center of a source width of a memory having a drain resistance and a source resistance which have the same resistances to each other. Accordingly, an area of the memory cell can be reduced.

### BRIEF DESCRIPTION OF THE DRAWINGS

FIGS. 1A and 1B respectively are a plan view and a partial sectional view of an example of a conventional nonvolatile memory structure,

FIG. 2 is a graph showing a relationship between the difference ΔVt of the threshold voltages and the summation of the source resistance and the drain resistance,

FIG. 3 is a graph showing a relationship between the difference ΔVt of the threshold voltages and the drain resistance,

FIGS. 4A and 4B respectively are a plan view and a partial sectional view of an example of a nonvolatile memory structure of the first embodiment, and

FIGS. 5A and 5B respectively are a plan view and a partial sectional view of an example of a nonvolatile memory structure of the second embodiment.

### DETAILED DESCRIPTION OF THE INVENTION

Embodiments of the present invention will be hereinafter described with reference to the drawings. In the following description, shapes, sizes, and positional relationships between elements are schematically shown to an extent so that a person skilled in the art can understand the present invention. Further, materials, numerical conditions and so on of the elements are merely presented in the context of preferred embodiments, and therefore the present invention is not limited to the following embodiments.

### First Embodiment

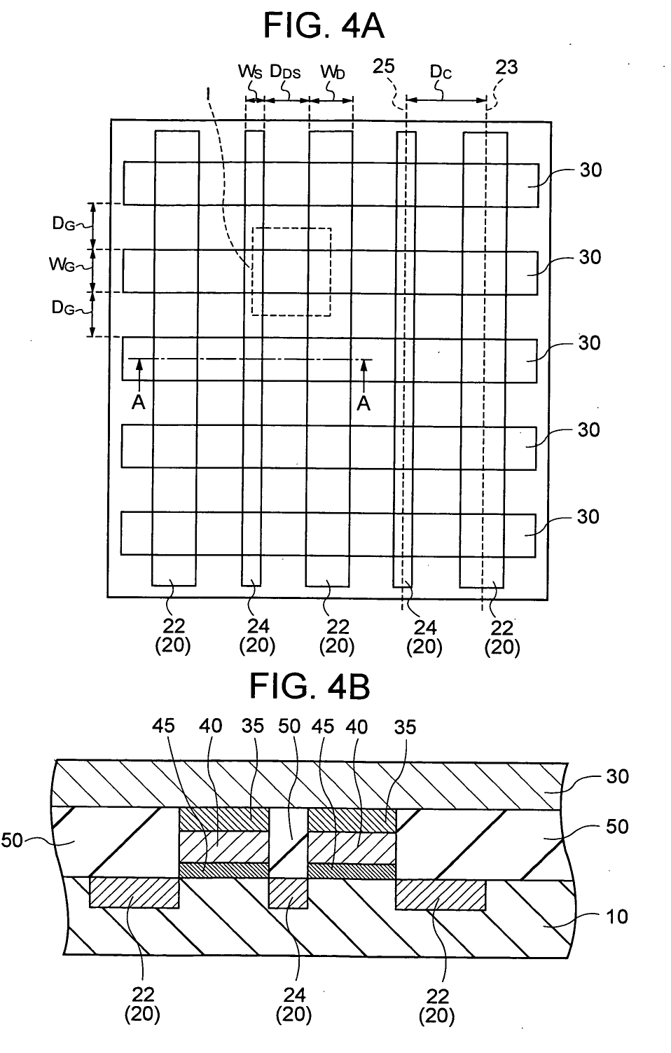

Referring to FIGS. 4A and 4B, a nonvolatile memory of a first embodiment having a bit line assembly consisting of bit lines formed by diffused layers will be described. FIGS. 4A and 4B schematically illustrate the nonvolatile memory of the first embodiment which has the bit line assembly. Specifically, FIG. 4A is a schematic front view of the conventional nonvolatile memory, and FIG. 4B is a schematic partial enlarged sectional view of FIG. 4A along the line A-A.

A plurality of drain regions 22 and a plurality of source regions 24, both of which are impurity diffused layers 20, are formed on a semiconductor chip 10 to extend parallel to each other. These impurity diffused layers 20 serve as bit lines. A plurality of control gate regions 30 are provided on the semiconductor chip 10 to form a striped shape extending in a direction perpendicular to a longitudinal direction of the drain regions 22 and the source regions 24.

A memory cell of the nonvolatile memory is defined at an intersection of the neighboring drain region 22 and source region 24 and one of the control gate regions 30 as shown by a dotted line I in FIG. 4A. Accordingly, memory cells of the nonvolatile memory of the first embodiment having a bit line assembly consisting of bit lines formed by diffused layers are arranged in an array pattern.

Each memory cell of the nonvolatile memory is provided with a floating gate 40. The floating gate 40 is formed on the semiconductor chip 10 via a floating gate insulation film 45, and the floating gate 40 is arranged between the drain region 22 and the source region 24. The control gate region 30 is formed either on the floating gate 40 via a control gate insulation film 35 or on the semiconductor chip 10 via an interlayer insulation film 50. A width of the drain region 22 along a channel direction and a width of the source region 24 along a channel direction are referred to as a drain width and a source width, respectively. It should be noted that the channel direction represents an extending direction of the control gate region 30 that is perpendicular to the drain region 22 and the source region 24.

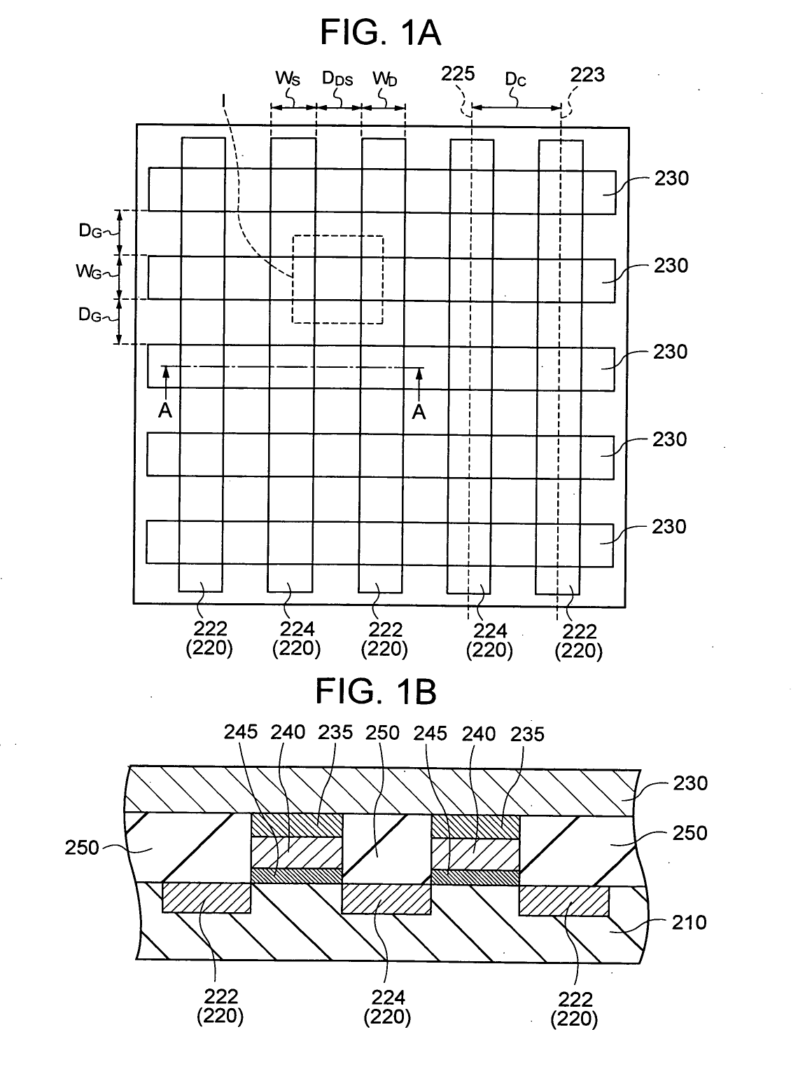

For example, the drain width W_{D} of the drain region 22 of the nonvolatile memory is 0.14 μm, and the source width W_{S} of the source region 24 is 0.06 μm. Under these conditions, when the impurity concentration of the drain region 22 is the same as that of the source region 24, an electrical resistance of the source region 24 between opposite ends thereof in its longitudinal direction (hereinafter simply referred to as a source resistance) is higher than an electrical resistance of the drain region 22 between opposite ends thereof in its longitudinal direction (hereinafter simply referred to as a drain resistance). Since the source width W_{S} of the source region 24 is reduced, a distance along the channel direction and extending between the center of the drain region 22 (shown by an imaginary center line 23 in FIG. 4A) and the center of the source region 24 (shown by an imaginary center line 25 in FIG. 4A), i.e., a distance D_{C} along a longitudinal direction of the control gate region 30 and extending between the center of the drain width W_{D} and the center of the source width W_{S} is shorter than that of the conventional nonvolatile memory described above with reference to FIGS. 1A and 1B having the drain resistance and the source resistance which have the same resistance to each other. It should be noted that, in the following description, the distance D_{C} between the center of the drain width W_{D} and the center of the source width W_{S} is referred to as a drain-source distance. In this embodiment, a distance D_{DS} between facing edges of the drain region 22 and the source region 24 which are adjacent to each other is 0.14 μm. Further, a width W_{G} of the control gate region 30 is 0.14 μm and a gap between adjacent two control gate regions, i.e., a distance between facing edges thereof is 0.14 μm.

In the above-described memory cell structure, an area of one memory cell is 0.28 μm×0.24 μm=0.0672 μm². On the other hand, an area of one memory cell of the conventional memory cell structure is 0.28 μm×0.28 μm=0.0784 μm². Accordingly, the above-described memory cell can reduce the memory cell area as compared with the conventional memory cell by approximately 15%.

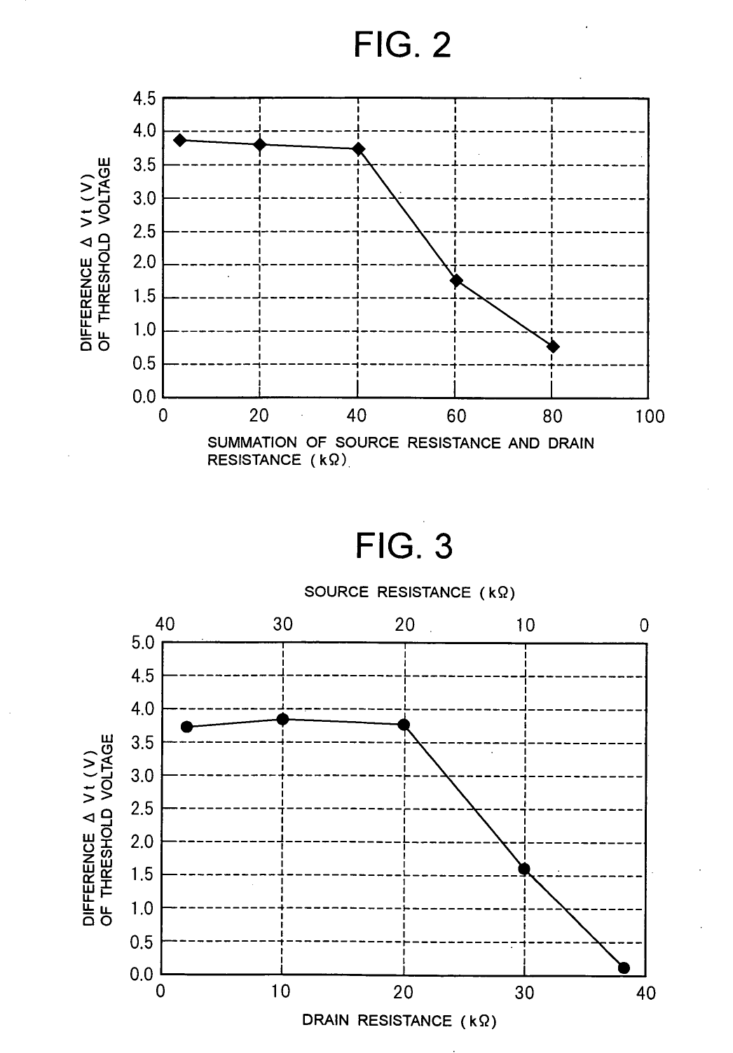

When the impurity concentration of the impurity diffused layers 20 serving as the drain region 22 and the source region 24 is the same as that of the above-described conventional nonvolatile memory shown in FIGS. 1A and 1B, the drain resistance and the source resistance become approximately 10 kΩ and 25 kΩ, respectively. In this case, the summation of the drain resistance and the source resistance is 35 kΩ. Since the drain resistance is 10 kΩ, as can be understood from FIG. 2 and FIG. 3, the writing characteristic does not deteriorate.

As shown in FIG. 2, the writing characteristic does not deteriorate until the summation of the source resistance and the drain resistance reaches 40 kΩ. Therefore, it is in principle possible that the source resistance and the drain resistance respectively have 20 kΩ by decreasing the width of the source region and the width of the drain region in half while keeping the drain region and the source region having the same sheet resistances to each other in a similar manner to the conventional structure shown in FIGS. 1A and 1B. However the width W_{S} and the width W_{D} of the impurity diffused layer may have deviations as much as approximately 0.02 μm due to manufacturing tolerance, even though it may be possible to manufacture the memory cells as a whole to have an exact size as expected. Specifically, when the impurity diffused layers (shown by a reference numeral 220 in FIG. 1A) are designed to be half widths of the conventional value, i.e., 0.07 μm, some of the impurity diffused layers 220 may have a width of approximately 0.05 μm, which may result in the resistance over 20 kΩ. As shown in FIG. 3, even though excess of the source resistance over 20 kΩ has little effect on the writing characteristic, excess of the drain resistance over 20 kΩ may deteriorate the writing characteristic.

On the contrary, according to the structure of the first embodiment, when the drain width W_{D} of the drain region 22 and the source width W_{S} of the source region 24 are deviated from the design value to be approximately 0.16 μm and 0.04 μm, respectively, the source resistance increases and the drain resistance decreases. In this case, the writing characteristic does not deteriorate. On the other hand, when the drain width W_{D} of the drain region 22 and the source width W_{S} of the source region 24 are deviated from the design value to be approximately 0.12 μm and 0.08 μm, respectively, the source resistance decreases and the drain resistance increases. In this case, even though the drain resistance increases, it does not exceed 20 kΩ. Accordingly, the writing characteristic does not deteriorate.

### Second Embodiment

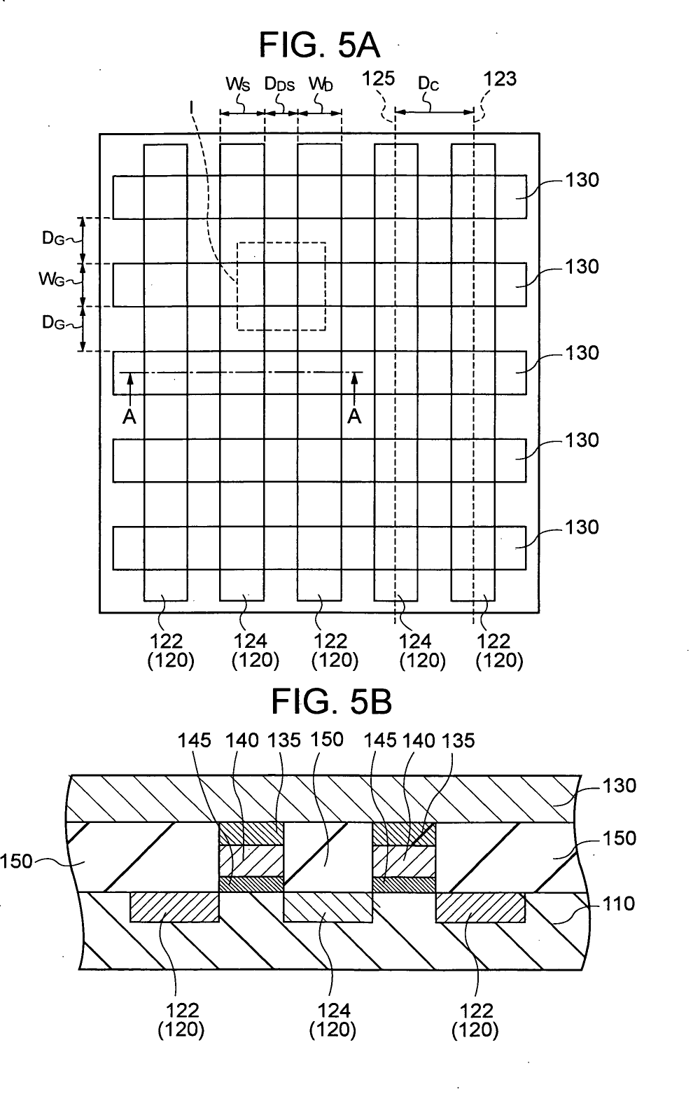

Referring to FIGS. 5A and 5B, a nonvolatile memory of a first embodiment having a bit line assembly consisting of bit lines formed by diffused layers will be described. FIGS. 5A and 5B schematically illustrate the nonvolatile memory of the second embodiment which has the bit line assembly. Specifically, FIG. 5A is a schematic front view of the conventional nonvolatile memory, and FIG. 5B is a schematic partial enlarged sectional view of FIG. 5A along the line A-A.

A plurality of drain regions 122 and a plurality of source regions 124, both of which are impurity diffused layers 120, are formed on a semiconductor chip 110 to extend parallel to each other. These impurity diffused layers 120 serve as bit lines. A plurality of control gate regions 130 are provided on the semiconductor chip 110 to form a striped shape extending in a direction perpendicular to a longitudinal direction of the drain regions 122 and the source regions 124.

A memory cell of the nonvolatile memory is defined at an intersection of the neighboring drain region 122 and source region 124 and one of the control gate regions 130 as shown by a dotted line I in FIG. 5A. Accordingly, memory cells of the nonvolatile memory of the second embodiment having a bit line assembly consisting of bit lines formed by diffused layers are arranged in an array pattern.

Each memory cell of the nonvolatile memory is provided with a floating gate 140. The floating gate 140 is formed on the semiconductor chip 110 via a floating gate insulation film 145, and the floating gate 140 is arranged between the drain region 122 and the source region 124. The control gate region 130 is formed either on the floating gate 140 via a control gate insulation film 135 or on the semiconductor chip 110 via an interlayer insulation film 150.

As described above with reference to FIG. 3, the writing characteristic does not deteriorate even though the source resistance is high. Accordingly, it is possible to decrease the impurity concentration of the impurity diffused layer serving as the source region. Decrease of the impurity concentration increases the sheet resistance between the source region and the drain region, thereby increasing a design margin against the off leak current. For example, when the drain width W_{D} of the drain region 122 is 0.14 μm and the source width W_{S} of the source region 124 is 0.14 μm, and the impurity concentration of the impurity diffused layer serving as the source region 124 is reduced as compared with the impurity concentration of the impurity diffused layer serving as the drain region 122, the drain resistance becomes 10 kΩ and the source resistance becomes 25 kΩ. This condition makes it possible to reduce a distance D_{DS} between facing edges of the drain region 122 and the source region 124 which are adjacent to each other to approximately 0.10 μm.

In this case, since a gap width between the drain region 122 and the source region 124 is decreased, a distance along the channel direction and extending between the center of the drain region 122 (shown by an imaginary center line 123 in figure) and the center of the source region 124 (shown by an imaginary center line 125 in figure), i.e., a distance D_{C} along a longitudinal direction of the control gate region 130 and extending between the center of the drain width W_{D} and the center of the source width W_{S} is shorter than that of the above-described conventional nonvolatile memory shown in FIGS. 1A and 1B. It should be noted that the width W_{G} of the control gate region 130 is 0.14 μm and the gap D_{G} between the control gate regions 130 is also 0.14 μm.

According to this cell structure of the second embodiment, an area of one memory cell is 0.28 μm×0.24 μm=0.0672 μm². On the contrary, an area of one memory cell of the conventional memory cell is 0.28 μm×0.28 μm=0.0784 μm². Accordingly, the memory cell of the second embodiment can reduce the memory cell area as compared with the conventional memory cell by approximately 15%.

This application is based on a Japanese patent application No. 2005-297159 which is herein incorporated by reference.

What is claimed is:

1. A nonvolatile memory comprising:
a plurality of drain regions and a plurality of source regions formed on a semiconductor chip so as to extend parallel to each other and extend between opposite ends of said semiconductor chip; and
a plurality of control gate regions formed on said semiconductor chip so as to extend in a direction perpendicular to an extending direction of said drain regions and source regions;
wherein resistance of each of said source regions per unit length along its longitudinal direction is higher than resistance of each of said drain regions per unit length along its longitudinal direction.

2. The nonvolatile memory according to claim 1, wherein a cross sectional area of each of said source regions in its longitudinal direction is smaller than a cross sectional area of each of said drain regions in its longitudinal direction.

3. The nonvolatile memory according to claim 1, wherein a width of each of said source regions is narrower than that of each of said drain regions.

4. The nonvolatile memory according to claim 1, wherein an impurity concentration of each of said source regions is lower than that of each of said drain regions.

5. The nonvolatile memory according to claim 1, wherein summation of an electric resistance of each of said source regions between opposite ends thereof in its longitudinal direction and an electric resistance of each of said drain regions between opposite ends thereof in its longitudinal direction is 40 kΩ or below, and an electric resistance of each of said drain regions between opposite ends thereof in its longitudinal direction is 20 kΩ or below.
